(19) United States
(12) Patent Application Publication
(10) Pub. No.: US 2013/0102152 A1
(43) Pub. Date: Apr. 25, 2013

(54) SEMICONDUCTOR MANUFACTURING APPARATUS AND METHOD OF MANUFACTURING SEMICONDUCTOR DEVICE

(71) Applicants: Yen-Chang CHAO, Taichung City (TW); Kei-Wei CHEN, Tainan City (TW); Ying-Lang WANG, Tien-Chung Village (TW)

(72) Inventors: Yen-Chang CHAO, Taichung City (TW); Kei-Wei CHEN, Tainan City (TW); Ying-Lang WANG, Tien-Chung Village (TW)

(73) Assignee: TAIWAN SEMICONDUCTOR MANUFACTURING COMPANY, LTD., Hsinchu (TW)

(21) Appl. No.: 13/277,609

(22) Filed: Oct. 20, 2011

(51) Int. Cl. H01L 21/306; B24B 55/00; H01L 21/304; B24B 41/06

(52) U.S. Cl. 438/692; 451/364; 451/442; 257/E21.23; 257/E21.237

(57) ABSTRACT

A semiconductor manufacturing apparatus includes at least one inner retaining ring, and an outer retaining ring. The at least one inner retaining ring applies a first pressure to the polishing pad, and retains a substrate on the polishing pad. The outer retaining ring applies a second pressure to the polishing pad, and retains the at least one inner retaining ring on the polishing pad. Control of the first pressure is independent with respect to control of the second pressure.

### TECHNICAL FIELD

The disclosure relates to a semiconductor manufacturing apparatus and a method of manufacturing semiconductor device, and more particularly, to a semiconductor manufacturing apparatus for polishing wafers and a method of manufacturing semiconductor device using the semiconductor manufacturing apparatus.

### BACKGROUND

In semiconductor device manufacturing processes, wafers undergo a variety of processes including a chemical mechanical polishing (CMP) process. A challenge in CMP apparatus design is to assure required CMP process performance and to achieve global planarization of the wafers.

### DESCRIPTION OF THE DRAWINGS

One or more embodiments are illustrated by way of example, and not by limitation, in the figures of the accompanying drawings, wherein elements having the same reference numeral designations represent like elements throughout and wherein:

FIG. 1 is a partial schematic cross-sectional view of a comparative example for illustrating a cause of an edge effect occurring during a CMP process;

FIG. 2A is a schematic cross-sectional view of a semiconductor manufacturing apparatus according to an embodiment;

FIG. 2B is a bottom plan view of an inner retaining ring of the semiconductor manufacturing apparatus depicted in FIG. 2A;

FIG. 2C is a bottom plan view of an outer retaining ring of the semiconductor manufacturing apparatus depicted in FIG. 2A;

FIG. 2D is a partial schematic cross-sectional view for illustrating pressures exerted on elements of the semiconductor manufacturing apparatus depicted in FIG. 2A;

FIG. 3A is a cross-sectional view of a semiconductor manufacturing apparatus according to another embodiment;

FIG. 3B is a bottom plan view of a first inner retaining ring of the semiconductor manufacturing apparatus depicted in FIG. 3A;

FIG. 3C is a bottom plan view of a second inner retaining ring of the semiconductor manufacturing apparatus depicted in FIG. 3A;

FIG. 3D is a partial schematic cross-sectional view for illustrating pressures exerted on elements of the semiconductor manufacturing apparatus depicted in FIG. 3A; and

FIG. 4 is a flowchart of a method of manufacturing a semiconductor device according to an embodiment.

### DETAILED DESCRIPTION

It is to be understood that the following disclosure provides many different embodiments or examples, for implementing different features of various embodiments. Specific examples of components and arrangements are described below to simplify the present disclosure. The present disclosure may, however, be embodied in many different forms and should not be construed as being limited to the embodiments set forth herein; rather, these embodiments are provided so that this description will be thorough and complete, and will fully convey the present disclosure to those of ordinary skill in the art. It will be apparent, however, that one or more embodiments may be practiced without these specific details.

In the drawings, the thickness and width of layers and regions are exaggerated for clarity. Like reference numerals in the drawings denote like elements. The elements and regions illustrated in the figures are schematic in nature, and thus relative sizes or intervals illustrated in the figures are not intended to limit the scope of the present disclosure.

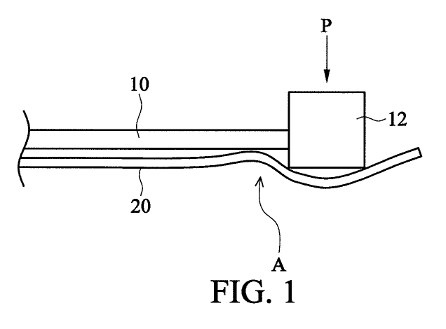

FIG. 1 is a partial schematic cross-sectional view of a comparative example for illustrating a cause of an edge effect occurring during a chemical mechanical polishing (CMP) process. A wafer 10 is surrounded by a single retaining ring 12 for retaining the wafer 10 within a carrier head (not shown). The wafer 10 and the retaining ring 12 are positioned on a polishing pad 20 during polishing of the wafer 10. During polishing of the wafer 10, overpressure P is applied to the retaining ring 12 against the polishing pad 20 in order to prevent the wafer 10 from slipping out from under the carrier head. The overpressure P may cause stress concentration in the polishing pad 20, resulting in deformation of the polishing pad 20 under the retaining ring 12. The deformation is generally indicated by an arrow A. The deformation of the polishing pad 20 is in the form of a wave propagating from the outer periphery of the retaining ring 12 toward other portions under an edge along an outer periphery of the wafer 10. The deformation of the polishing pad 20 results in an edge effect which is the tendency of over-grinding at the edge of the wafer 10 in comparison with at the center of the wafer 10. Additionally, the overpressure P can lead to excessive wear of the retaining ring 12 and can generate wear debris which may cause scratches on the wafer 10.

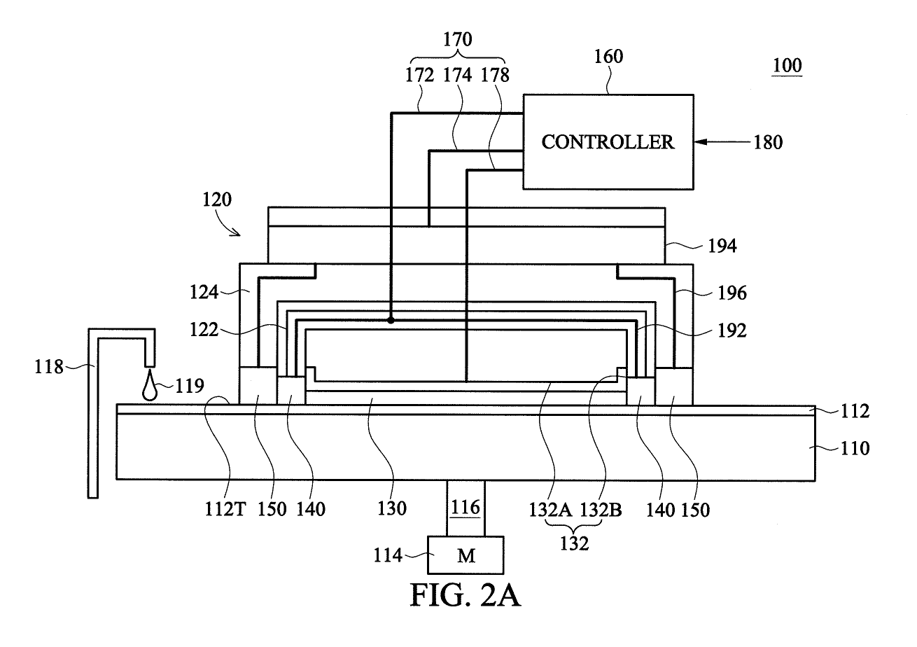

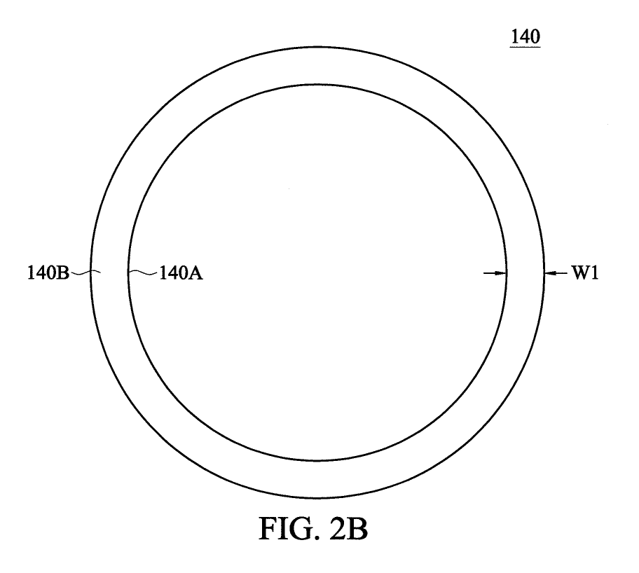

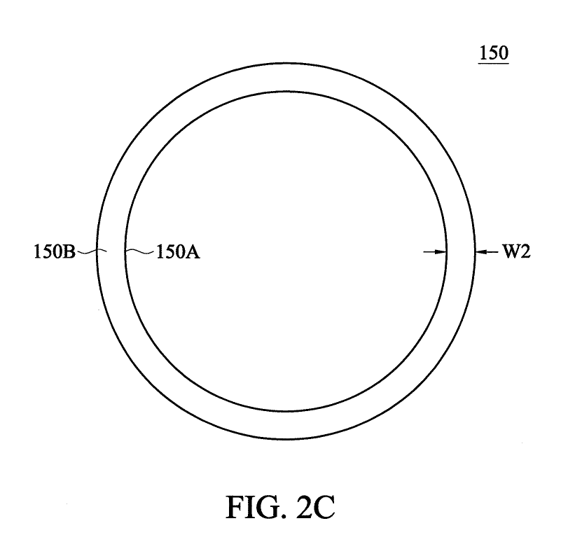

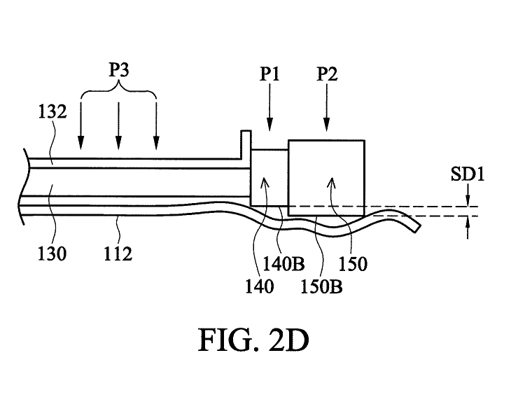

FIG. 2A is a schematic cross-sectional view of a semiconductor manufacturing apparatus 100 according to an embodiment of the present disclosure. In one or more embodiments, the semiconductor manufacturing apparatus 100 is a chemical mechanical polishing (CMP) apparatus.

The semiconductor manufacturing apparatus 100 comprises a platen 110 and a carrier head 120 disposed over the platen 110. A polishing pad 112 is placed on a top surface of the platen 110. The platen 110 is connected to a motor 114 via a shaft 116. A slurry line 118 is disposed adjacent a top surface 112T of the polishing pad 112. Slurry 119 is supplied onto the polishing pad 112 through the slurry line 118.

The motor 114 rotates the platen 110, and the polishing pad 112 positioned on the top surface of the platen 110, by rotating the shaft 116. The carrier head 120 holds a substrate 130 on the polishing pad 112. During a CMP process, the substrate 130 held by the carrier head 120 is in contact with the polishing pad 112 by a membrane 132. The membrane 132 is maintained within the carrier head 120. The membrane 132 downwardly presses the substrate 130 against the polishing pad 112. The membrane 132 is a sheet having a horizontal circular portion 132A facing a backside of the substrate 130, and a vertical edge portion 132B vertically extending from the circumference of the horizontal circular portion 132A. In some embodiments, the membrane 132 is formed of a flexible and elastic fluid-impermeable material. For example, the membrane 132 includes at least one of neoprene, chloroprene, ethylene propylene rubber, or silicone, but is not limited by the above-mentioned materials.

During polishing of the substrate 130, the polishing pad 112 rotates along with the platen 110 at a constant rotation rate. In some embodiments, the carrier head 120 holding the substrate 140 moves back and forth between a center portion and an edge portion of the polishing pad 112 during polishing of the substrate 130. In some embodiments, the carrier head 120 rotates about an axis of a drive shaft (not shown) connected to the carrier head 120 and the slurry 119 supplied from the slurry line 118 is spread out on the top surface 112T of the polishing pad 112 during polishing of the substrate 130. The substrate 130 is polished by the slurry 119 and/or the polishing pad 112 during movement of the carrier head 120 and the polishing pad 112.

An inner retaining ring 140 and an outer retaining ring 150 are secured to the carrier head 120. The inner retaining ring 140 and the outer retaining ring 150 surround the substrate 130 and the membrane 132. The inner retaining ring 140 is interposed between the membrane 132 and the outer retaining ring 150. The inner retaining ring 140 retains the substrate 130 within the carrier head 120 without downwardly pressing the substrate 130 during polishing of the substrate 130. The outer retaining ring 150 surrounds the inner retaining ring 140 in order to retain the inner retaining ring 140 within the carrier head 120.

The carrier head 120 includes an inner carrier body 122 for fixing the inner retaining ring 140, and an outer carrier body 124 for fixing the outer retaining ring 150. The inner carrier body 122 is spaced apart from the outer carrier body 124. Although the specific shapes of each of the inner carrier body 122 and the outer carrier body 124 are shown and described, the shapes of each of the inner carrier body 122 and the outer carrier body 124 are not limited thereto, and various shapes of each of the inner carrier body 122 and the outer carrier body 124 may be used.

The inner retaining ring 140 is secured at a bottom edge portion of the inner carrier body 122 by a first fixing device (not shown). The outer retaining ring 150 is secured at bottom edge portion of the outer carrier body 124 by a second fixing device (not shown). In some embodiments, the first and second fixing devices are bolts.

A bottom surface of the outer retaining ring 150 abuts the polishing pad 112 in order to hold the carrier head 120 in a specified position during polishing. The substrate 130 is confined by the inner retaining ring 140 and the outer retaining ring 150 so that the substrate 130 is movable along with the carrier head 120.

FIG. 2B is a bottom plan view of the inner retaining ring 140. The inner retaining ring 140 is a substantially annular ring. The inner retaining ring 140 has an inner most circumferential surface 140A for retaining the substrate 130 within the carrier head 120. The inner retaining ring 140 has a bottom surface 140B for applying pressure to the polishing pad 112. The bottom surface 140B is substantially flat. In some embodiments, the bottom surface 140B has channels through which the slurry 119 is transported to and from the substrate 130. The bottom surface 140B has a radial direction width W1.

FIG. 2C is a bottom plan view of the outer retaining ring 150. The outer retaining ring 150 is a substantially annular ring. The outer retaining ring 150 has an inner circumferential surface 150A for retaining the inner retaining ring 140 within the carrier head 120. The outer retaining ring 150 has a bottom surface 150B for applying pressure to the polishing pad 112. The bottom surface 150B is substantially flat. In some embodiments, the bottom surface 150B has channels through which the slurry 119 is transported to and from the substrate 130. The bottom surface 150B has a radial direction width W2.

The radial direction width W1 of the inner retaining ring 140 is smaller than the radial direction width W2 of the outer retaining ring 150, although it is not particularly limited thereto. In some embodiments, the radial direction width W1 is equal to or greater than the radial direction width W2. The bottom surface 140B has a surface area smaller than a surface area of the bottom surface 150B, although it is not particularly limited thereto. In some embodiments, the bottom surface 140B has a surface area equal to or greater than a surface area of the bottom surface 150B.

In one or more embodiments, each of the inner retaining ring 140 and the outer retaining ring 150 is formed of aluminum (Al), Al alloy, stainless steel, copper (Cu), gold (Au), palladium (Pd), ceramic, hard polymers such as polyphenylene sulfide (PPS) and polyetherether-ketone (PEEK), or combinations thereof. In some embodiments, the inner retaining ring 140 and the outer retaining ring 150 include the same material. In some embodiments, the inner retaining ring 140 and the outer retaining ring 150 include different materials.

FIG. 2D is a partial schematic cross-sectional view for illustrating pressures exerted on the polishing pad 112 by the inner retaining ring 140, the outer retaining ring 150, and the membrane 132.

The inner retaining ring 140 applies a first pressure P1 to the polishing pad 112 during polishing. The outer retaining ring 150 applies a second pressure P2 to the polishing pad 112 during polishing. The membrane 132 applies a third pressure P3 to the substrate 130 against the polishing pad 112 during polishing.

The first, second, and third pressures P1, P2, and P3 are independently controlled by a controller 160 (FIG. 2A). Control of the first pressure P1 is independent with respect to control of the second pressure P2. Control of the third pressure P3 is independent with respect to control of the first pressure P1 and control of the second pressure P2. Referring to FIG. 2A, the pressure controller 160 is connected to the carrier head 120 by way of a pneumatic line assembly 170 including a first pneumatic line 172, a second pneumatic line 174, and a third pneumatic line 178. During polishing of the substrate 130, pressure media 180, for example air, is introduced into the controller 160. The controller 160 supplies the pressure media 180 to the pneumatic line assembly 170. The controller 160 independently controls each pressure of the pressure media 180 passing through the first, second, and third pneumatic lines 172, 174, and 178 in order to independently control forces applied to the inner retaining ring 140, the outer retaining ring 150, and the membrane 132.

The inner retaining ring 140 is downwardly pressed against the polishing pad 112 by the pressure media 180 sequentially passing through the first pneumatic line 172 and a first inner tube 192 such that the inner retaining ring 140 can retain the substrate 130 within the carrier head 120. The first pressure P1 exerted on the polishing pad 112 by the inner retaining rings 140 suppresses pad deformation in a region surrounding the substrate 130, thereby preventing the pad deformation from propagating toward the substrate 130.

The outer retaining ring 150 is downwardly pressed against the polishing pad 112 by the pressure media 180 sequentially passing through the second pneumatic line 174, a carrier chamber 194, and a second inner tube 196 such that the outer retaining ring 150 retains the inner retaining ring 140 within the carrier head 120 and holds the carrier head 120 in a desired position during polishing. Because the inner retaining ring 140 for retaining the substrate 130 is interposed between the outer retaining ring 150 and the substrate 130, the second pressure P2 is controlled at a relatively low level in comparison with the case of absence of the inner retaining ring 140. Therefore, the bottom surface 150B of the outer retaining ring 150 contacts the polishing pad 112 at a relatively low pressure. By reducing the second pressure P2 applied to the polishing pad 112 by the outer retaining ring 150, friction between the outer retaining ring 150 and the polishing pad 112 is reduced, thereby decreasing wear of the outer retaining ring 150. Therefore, it is possible to decrease scratches on the substrate 130 caused by debris of the outer retaining ring 150, and to increase life span of the outer retaining ring 150.

The membrane 132 is downwardly pressed by the pressure media 180 passing through the third pneumatic line 178 such that the membrane 132 downwardly presses the backside of the substrate 130 against the polishing pad 112. In some embodiments, force of the pressure media 180 is applied to a plurality of points on the backside of the substrate 130 against the polishing pad 112 to achieve a uniform polishing rate within the substrate 130.

In one or more embodiments, the controller 160 controls pressures in the pneumatic line assembly 170 such that at least one of the first pressure P1 and the second pressure P2 is greater than the third pressure P3. In some embodiments, the controller 160 controls pressures in the pneumatic line assembly 170 such that the first pressure P1 is greater than, less than, or equal to the second pressure P2. When the second pressure P2 is greater than the first pressure P1, a step difference SD1 can be formed between the bottom surface 140B and the bottom surface 150B, as depicted in FIG. 2D. In some embodiments, the controller 160 independently controls the first pressure P1 and the second pressure P2, such that the step difference SD1 remains within an acceptable process window during the CMP process. In one or more embodiments, the controller 160 controls the first pressure P1 and the second pressure P2 such that the bottom surface 140B is on the same plane with the bottom surface 150B as depicted in FIG. 2A.

By independently controlling the first, second, and third pressures P1, P2, and P3 by using the controller 160, deformation of the polishing pad 112 is effectively suppressed during polishing of the substrate 130, and the polishing removal rate near the edge of the substrate 130 is modulated, thereby achieving global planarization.

When the CMP process is completed, the substrate 130 is lifted up from the polishing pad 112 by the carrier head 120. In some embodiments, vacuum is applied to the backside of the substrate 130 within the carrier head 120 to chuck the substrate 130 against the membrane 132.

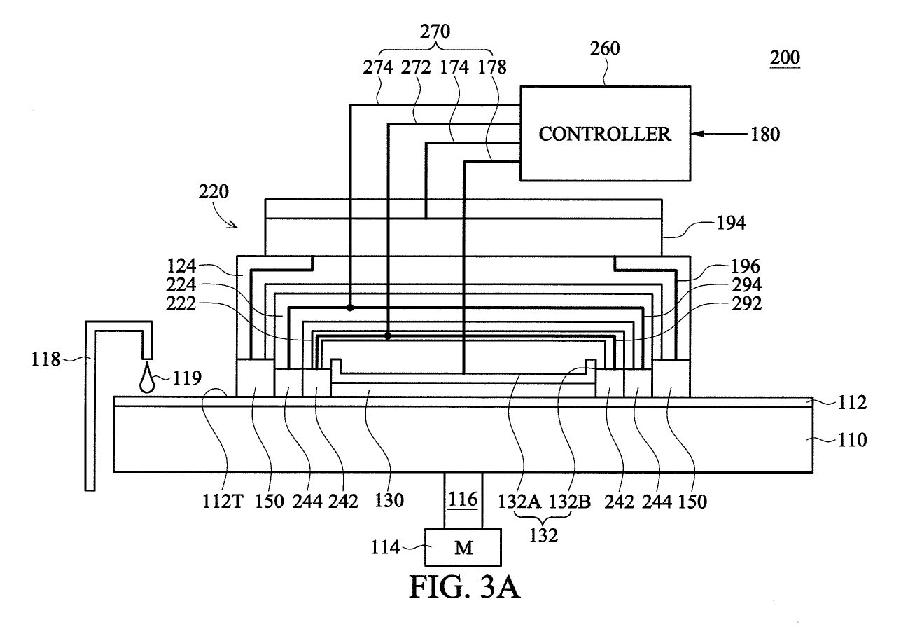

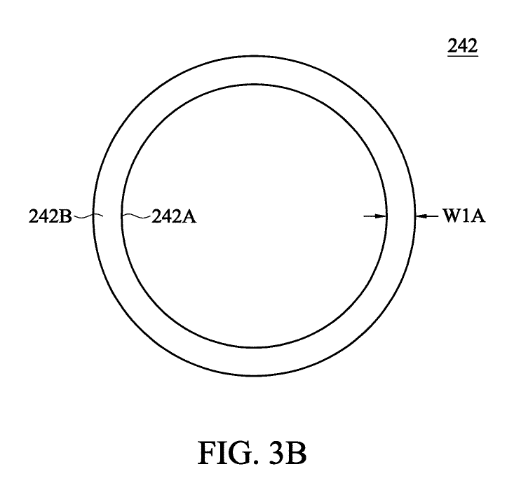

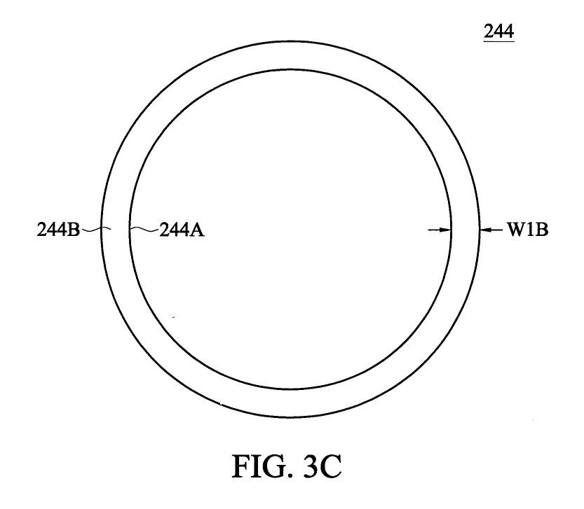

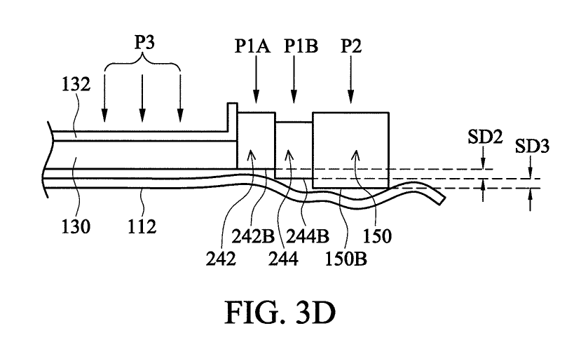

FIG. 3A is a schematic cross-sectional view of a semiconductor manufacturing apparatus 200 according to another embodiment of the present disclosure. In FIG. 3A, the features are the same as or similar to like-numbered features described with reference to FIG. 2A. Therefore, the descriptions thereof will be omitted to avoid repetition.

The semiconductor manufacturing apparatus 200 comprises a plurality of inner retaining rings including a first inner retaining ring 242 and a second inner retaining ring 244. In some embodiments, the semiconductor manufacturing apparatus 200 comprises three or more inner retaining rings. The first inner retaining ring 242 retains the substrate 130 within a carrier head 220 without downwardly pressing the substrate 130 during polishing of the substrate 130. The second inner retaining ring 244 is interposed between the first inner retaining ring 242 and the outer retaining ring 150. The second inner retaining ring 244 retains the first inner retaining ring 242 within the carrier head 220. The outer retaining ring 150 retains the second inner retaining ring 244 within the carrier head 220. Each of the first inner retaining ring 242 and the second inner retaining ring 244 applies an independently controlled pressure to the polishing pad 112.

The first inner retaining ring 242 and the second inner retaining ring 244 are secured to the carrier head 220. The carrier head 220 includes a first inner carrier body 222 for fixing the first inner retaining ring 242, a second inner carrier body 224 for fixing the second inner retaining ring 244, and the outer carrier body 124 for fixing the outer retaining ring 150.

The first inner carrier body 222, the second inner carrier body 224, and the outer carrier body 124 are spaced apart from one another. Although the specific shapes of each of the first inner carrier body 222 and the second inner carrier body 224 are shown and described, the shapes of each of the first inner carrier body 222 and the second inner carrier body 224 are not limited thereto, and various shapes of each of the first inner carrier body 222 and the second inner carrier body 224 may be used.

The first inner retaining ring 242 is secured at a bottom edge portion of the first inner carrier body 222 by a third fixing device (not shown). The second inner retaining ring 244 is secured at a bottom edge portion of the second inner carrier body 224 by a fourth fixing device (not shown). In some embodiments, the third and fourth fixing devices are bolts. The substrate 130 is confined by the first inner retaining ring 242, the second inner retaining ring 244, and the outer retaining ring 150 so that the substrate 130 moves along with the carrier head 220.

FIG. 3B is a bottom plan view of the first inner retaining ring 242. The first inner retaining ring 242 is a substantially annular ring. The first inner retaining ring 242 has an innermost circumferential surface 242A for retaining the substrate 130 within the carrier head 220. The first inner retaining ring 242 has a bottom surface 242B for applying an independently controlled pressure to the polishing pad 112. The bottom surface 242B is substantially flat. In some embodiments, the bottom surface 242B has channels through which the slurry 119 is transported to and from the substrate 130. The bottom surface 242B of the first inner retaining ring 242 has a radial direction width W1A.

FIG. 3C is a bottom plan view of the second inner retaining ring 244. The second inner retaining ring 244 is a substantially annular ring. The second inner retaining ring 244 has an inner circumferential surface 244A for retaining the first inner retaining ring 242 within the carrier head 220. The second inner retaining ring 244 is retained within the carrier head 220 by the inner circumferential surface 150A of the outer retaining ring 150 depicted in FIG. 2C. The second inner retaining ring 244 has a bottom surface 244B for applying an independently controlled pressure to the polishing pad 112. The bottom surface 244B is substantially flat. In some embodiments, the bottom surface 244B has channels through which the slurry 119 is transported to and from the substrate 130. The bottom surface 244B of the second inner retaining ring 244 has a radial direction width W1B.

In some embodiments, at least one of the bottom surfaces 242B and 244B has a surface area smaller than the surface area of the bottom surface 150B of the outer retaining ring 150. At least one of the radial direction widths W1A and W1B is smaller than the radial direction width W2 of the outer retaining ring 150, although it is not particularly limited thereto. In some embodiments, at least one of the radial direction widths W1A and W1B is greater than or equal to the radial direction width W2 of the outer retaining ring 150.

In one or more embodiments, each of the first and second inner retaining rings 242 and 244 is formed of Al, Al alloy, stainless steel, Cu, Au, Pd, ceramic, hard polymers such as PPS and PEEK, or combinations thereof. In some embodiments, the first and second inner retaining rings 242 and 244, and the outer retaining ring 150 include the same material. In some embodiments, the first and second inner retaining rings 242 and 244, and the outer retaining ring 150 include different materials.

FIG. 3D is a partial schematic cross-sectional view for illustrating pressures exerted on the polishing pad 112 by the first inner retaining ring 242, the second inner retaining ring 244, the outer retaining ring 150, and the membrane 132.

The first inner retaining ring 242 applies an independently controlled inside first pressure P1A to the polishing pad 112 during polishing. The second inner retaining ring 244 applies an independently controlled outside first pressure P1B to the polishing pad 112 during polishing.

The inside first pressure P1A, the outside first pressure P1B, the second pressure P2, and the third pressure P3 are independently controlled by a controller 260. Control of the inside first pressure P1A, control of the outside first pressure P1B, control of the second pressure P2, and control of the third pressure P3 are independent with respect to one another. The controller 260 is connected to the carrier head 220 by way of a pneumatic line assembly 270 including an inside first pneumatic line 272, an outside first pneumatic line 274, the second pneumatic line 174, and the third pneumatic line 178. During polishing, the pressure media 180 is introduced into the fluid controller 260. The fluid controller 260 supplies the pressure media 180 to the pneumatic line assembly 270. The fluid controller 260 independently controls the pressure of the pressure media 180 within each of the inside first pneumatic line 272, the outside first pneumatic line 274, the second pneumatic line 174, and the third pneumatic line 178 in order to independently control forces applied to the first inner retaining ring 242, the second inner retaining ring 244, the outer retaining ring 150, and the membrane 132.

The first inner retaining ring 242 is downwardly pressed against the polishing pad 112 by the pressure media 180 sequentially passing through the inside first pneumatic line 272 and an inside first inner tube 292 in order to retain the substrate 130 within the carrier head 220. The second inner retaining ring 244 is downwardly pressed against the polishing pad 112 by the pressure media 180 sequentially passing through the outside first pneumatic line 274 and an outside first inner tube 294 in order to retain the first inner retaining ring 242 within the carrier head 220. The inside first pressure P1A is applied to the polishing pad 112 by the first inner retaining ring 242. The outside first pressure P1B is applied to the polishing pad 112 by the second inner retaining ring 244. The inside first pressure P1A and the outside first pressure P1B can absorb pad deformation in a region surrounding the substrate 130, thereby preventing the pad deformation from propagating toward the substrate 130.

Because the first and second inner retaining rings 242 and 244 are interposed between the outer retaining ring 150 and the substrate 130, the second pressure P2 can be controlled at a relatively low level in comparison with the case of absence of the first and second inner retaining rings 242 and 244.

In one or more embodiments, the fluid controller 260 controls pressure in the pneumatic line assembly 270 such that at least one of the pressures P1A, P1B, and P2 is greater than the third pressure P3. In some embodiments, the fluid controller 260 controls pressure in the pneumatic line assembly 270 such that the pressures P1A, P1B, and P2 are the same as or different from one another. When the second pressure P2 is greater than the inside first pressure P1A, a step difference SD2 is formed between the bottom surface 242B of the first inner retaining ring 242 and the bottom surface 150B of the outer retaining ring 150. Similarly, a step difference SD3 is formed between the bottom surface 244B of the second inner retaining ring 244 and the bottom surface 150B of the outer retaining ring 150 when the second pressure P2 is greater than the outside first pressure P1B. In some embodiments, the fluid controller 260 independently controls the pressures P1A, P1B, and P2 such that the step differences SD2 and SD3 remain within an acceptable process window during the CMP process. In one or more embodiments, the fluid controller 260 independently controls the pressures P1A, P1B, and P2 such that the bottom surfaces 242B and 244B are on the same plane with the bottom surface 150B of the outer retaining ring 150 as depicted in FIG. 3A.

By independently controlling the pressures P1A, P1B, P2, and P3 by using the fluid controller 260, deformation of the polishing pad 112 can be effectively suppressed during polishing of the substrate 130, and the polishing removal rate near the edge of the substrate 130 is modulated, thereby achieving global planarization.

When the CMP process is completed, the substrate 130 is lifted up from the polishing pad 112 by the carrier head 220. In some embodiments, vacuum is applied to the backside of the substrate 130 within the carrier head 220 to chuck the substrate 130 against the membrane 132.

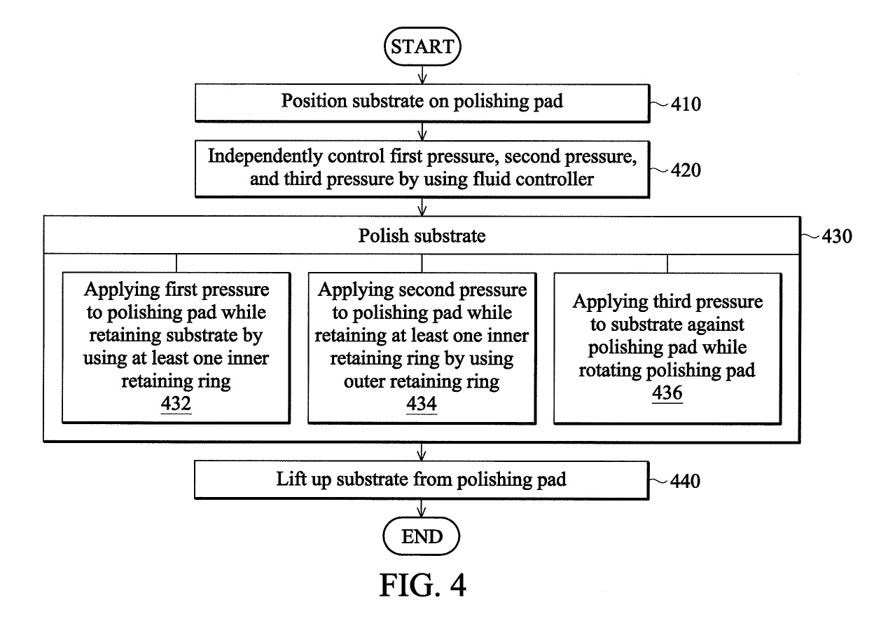

FIG. 4 is a flowchart of an exemplary method of manufacturing a semiconductor device according to an embodiment. The flow chart of FIG. 4 relates to a method of manufacturing the semiconductor device by using the semiconductor manufacturing apparatus 100 depicted in FIG. 2A, or by using the semiconductor manufacturing apparatus 200 depicted in FIG. 3A. For the sake of clarity, reference numerals of the semiconductor manufacturing apparatus 100 will be used for explaining the method shown in the flow chart of FIG. 4. However, the semiconductor manufacturing apparatus 200 may be used in a similar fashion.

In operation 410, the substrate 130 is positioned on the polishing pad 112 by using the carrier head 120.

In operation 420, the first pressure P1, the second pressure P2, and the third pressure P3 are independently controlled by using the controller 160 from which the first pneumatic line 172, the second pneumatic line 174, and the third pneumatic line 178 are separately branched.

In operation 430, the substrate 130 is polished by the slurry 119 and/or the polishing pad 112 in the semiconductor manufacturing apparatus 100. Operation 430 includes sub-operations 432, 434, and 436. During polishing of the substrate 130 in operation 430, sub-operations 432, 434, and 436 are simultaneously performed.

In sub-operation 432, the first pressure P1 is applied to the polishing pad 112 by using the inner retaining ring 140 downwardly pressed by the pressure media 180 passing through the first pneumatic line 172 and the first inner tube 192, while retaining the substrate 130 without downwardly pressing the substrate 130 by using the inner retaining ring 140. In case of using the semiconductor manufacturing apparatus 200 depicted in FIG. 3A, the inside first pressure P1A and the outside first pressure P1B are applied to the polishing pad 112 by using the first inner retaining ring 242 and the second inner retaining ring 244, respectively, while retaining the substrate 130 by using the first inner retaining ring 242.

In sub-operation 434, the second pressure P2 is applied to the polishing pad 112 by using the outer retaining ring 150 downwardly pressed by the pressure media 180 passing through the second pneumatic line 174, the carrier chamber 194, and the second inner tube 196, while retaining the inner retaining ring 140 by using the outer retaining ring 150.

In sub-operation 436, the third pressure P3 is applied to the substrate 130 against the polishing pad 112 by using the membrane 132 downwardly pressed by the pressure media 180 passing through the third pneumatic line 178, while rotating the polishing pad 112.

In operation 440, the substrate 130 is lifted up from the polishing pad 112 by the carrier head 120 when the polishing of the substrate 130 is completed.

According to one or more embodiments described with reference to FIG. 4, the substrate is polished while applying the independently controlled pressures to the inner retaining ring, to the outer retaining ring, and to the substrate against the polishing pad. In manufacturing the semiconductor device by using the semiconductor manufacturing apparatus including the inner retaining ring and the outer retaining ring, deformation of the polishing pad is suppressed and the edge effect caused by the deformation can be prevented, thereby achieving the CMP process performance required for manufacturing advanced integrated circuits.

According to some embodiments, a semiconductor manufacturing apparatus includes at least one inner retaining ring, and an outer retaining ring. The at least one inner retaining ring applies a first pressure to the polishing pad, and retains a substrate on the polishing pad. The outer retaining ring applies a second pressure to the polishing pad, and retains the at least one inner retaining ring on the polishing pad. Control of the first pressure is independent with respect to control of the second pressure.

According to some embodiments, a semiconductor manufacturing apparatus comprises a carrier head for holding a substrate on a polishing pad, an inner retaining ring, an outer retaining ring, and a fluid controller. The inner retaining ring is connected to the carrier head. The inner retaining ring has a bottom surface for applying a first pressure to the polishing pad and has an innermost circumferential surface for retaining the substrate. The outer retaining ring is connected to the carrier head. The outer retaining ring has a bottom surface for applying a second pressure to the polishing pad and has an inner circumferential surface for retaining the inner retaining ring. The fluid controller is connected to the inner retaining ring and the outer retaining ring. The fluid controller is configured to independently control the first pressure and the second pressure with respect to each other.

According to some embodiments, a method of manufacturing a semiconductor device comprises positioning a substrate on a polishing pad by using a carrier head including at least one inner retaining ring and an outer retaining ring. The first pressure is applied to the polishing pad by using the at least one inner retaining ring, while retaining the substrate without downwardly pressing the substrate by using the at least one inner retaining ring. The second pressure is applied to the polishing pad by using the outer retaining ring, while retaining the at least one inner retaining ring by using the outer retaining ring.

While the present disclosure has been particularly shown and described with reference to example embodiments thereof, a skilled person in the art will appreciate that there can be many embodiment variations of this disclosure. Although the embodiments and their features have been described in detail, it should be understood that various changes, substitutions and alterations can be made herein without departing from the spirit and scope of the embodiments.

The above method embodiment shows exemplary operations, but they are not necessarily required to be performed in the order shown. Operations or sub-operations may be added, replaced, changed order, and/or eliminated as appropriate, in accordance with the spirit and scope of embodiment of the disclosure. Embodiments that combine different claims and/or different embodiments are within scope of the disclosure and will be apparent to those skilled in the art after reviewing this disclosure.

What is claimed is:

1. A semiconductor manufacturing apparatus, comprising:
at least one inner retaining ring for applying a first pressure to a polishing pad, the at least one inner retaining ring having an innermost circumferential surface for retaining a substrate on the polishing pad; and
an outer retaining ring for applying a second pressure to the polishing pad, and arranged to retain the at least one inner retaining ring on the polishing pad,
wherein control of the first pressure is independent with respect to control of the second pressure.

2. The semiconductor manufacturing apparatus of claim 1, wherein the at least one inner retaining ring includes:
a first inner retaining ring for retaining the substrate; and
a second inner retaining ring interposed between the first inner retaining ring and the outer retaining ring.

3. The semiconductor manufacturing apparatus of claim 2, wherein
the first inner retaining ring has a bottom surface for applying an independently controlled inside first pressure to the polishing pad, and
the second inner retaining ring has a bottom surface for applying an independently controlled outside first pressure to the polishing pad.

4. The semiconductor manufacturing apparatus of claim 1, further comprising a membrane for applying a third pressure to the substrate against the polishing pad, control of the third pressure being independent with respect to control of the first pressure and control of the second pressure.

5. A semiconductor manufacturing apparatus, comprising:
a carrier head for holding a substrate on a polishing pad;
an inner retaining ring connected to the carrier head, the inner retaining ring having a bottom surface for applying a first pressure to the polishing pad and having an innermost circumferential surface for retaining the substrate;
an outer retaining ring connected to the carrier head, the outer retaining ring having a bottom surface for applying a second pressure to the polishing pad and having an inner circumferential surface for retaining the inner retaining ring; and
a fluid controller connected to the inner retaining ring and the outer retaining ring, the fluid controller being configured to independently control the first pressure and the second pressure with respect to each other.

6. The semiconductor manufacturing apparatus of claim 5, further comprising a membrane for applying a third pressure to the substrate against the polishing pad, control of the third pressure being independent with respect to control of the first pressure and control of the second pressure.

7. The semiconductor manufacturing apparatus of claim 6, wherein the fluid controller is configured to independently control the first pressure, the second pressure, and the third pressure such that at least one of the first pressure and the second pressure is greater than the third pressure.

8. The semiconductor manufacturing apparatus of claim 5, wherein the fluid controller is configured to independently control the first pressure and the second pressure to form a step difference between the bottom surface of the inner retaining ring and the bottom surface of the outer retaining ring.

9. The semiconductor manufacturing apparatus of claim 5, wherein the fluid controller is configured to independently control the first pressure and the second pressure such that the bottom surface of the inner retaining ring is on the same plane with the bottom surface of the outer retaining ring.

10. The semiconductor manufacturing apparatus of claim 5, wherein the bottom surface of the inner retaining ring has a surface area smaller than a surface area of the bottom surface of the outer retaining ring.

11. The semiconductor manufacturing apparatus of claim 5, wherein the inner retaining ring has a radial direction width smaller than a radial direction width of the outer retaining ring.

12. The semiconductor manufacturing apparatus of claim 5, wherein the carrier head includes a first carrier body for securing the inner retaining ring, and a second carrier body for securing the outer retaining ring, the first carrier body being inside the second carrier body.

13. The semiconductor manufacturing apparatus of claim 5, wherein at least one of the inner retaining ring and the outer retaining ring is formed of aluminum (Al), Al alloy, stainless steel, copper (Cu), gold (Au), palladium (Pd), ceramic, polymer, or combinations thereof.

14. The semiconductor manufacturing apparatus of claim 5, wherein the inner retaining ring and the outer retaining ring include the same material.

15. A method of manufacturing a semiconductor device, comprising:
positioning a substrate on a polishing pad by using a carrier head including at least one inner retaining ring and an outer retaining ring;
applying a first pressure to the polishing pad by using the at least one inner retaining ring while retaining the substrate without downwardly pressing the substrate by using the at least one inner retaining ring; and
applying a second pressure to the polishing pad by using the outer retaining ring while retaining the at least one inner retaining ring by using the outer retaining ring.

16. The method of claim 15, further comprising:
controlling the first pressure and the second pressure independently by using a fluid controller.

17. The method of claim 15, further comprising:
applying a third pressure to the substrate against the polishing pad by using a membrane while rotating the polishing pad.

18. The method of claim 17, further comprising:
controlling the first pressure, the second pressure, and the third pressure independently by using a fluid controller.

19. The method of claim 18, wherein the fluid controller controls the first pressure, the second pressure, and the third pressure such that at least one of the first pressure and the second pressure is greater than the third pressure.

20. The method of claim 17, wherein the applying of the first pressure, the applying of the second pressure, and the applying of the third pressure are performed simultaneously.
